(19) United States
(12) Patent Application Publication
(10) Pub. No.: US 2026/0082812 A1
(43) Pub. Date: Mar. 19, 2026

(54) MAGNETIC MEMORY DEVICE

(71) Applicant: Kioxia Corporation, Tokyo (JP)

(72) Inventors: Kazuya SAWADA, Seoul (KR); Tadaaki OIKAWA, Seoul (KR); Soichi OIKAWA, Seoul (KR); Kenji FUKUDA, Seoul (KR)

(73) Assignee: Kioxia Corporation, Tokyo (JP)

(21) Appl. No.: 19/073,082

(22) Filed: Mar. 7, 2025

(30) Foreign Application Priority Data
Sep. 13, 2024 (JP) 2024-159050

(51) Int. Cl. H10N 50/10; G11C 11/16; H10N 50/85

(52) U.S. Cl. CPC H10N 50/10; G11C 11/161; G11C 11/1659; G11C 11/1673; G11C 11/1675; H10N 50/85

(57) ABSTRACT

According to one embodiment, a magnetic memory device includes a magnetoresistive effect element. The magnetoresistive effect element includes a first ferromagnetic layer, a second ferromagnetic layer, a third ferromagnetic layer, a first nonmagnetic layer provided between the first ferromagnetic layer and the second ferromagnetic layer, a second nonmagnetic layer provided between the second ferromagnetic layer and the third ferromagnetic layer, a third nonmagnetic layer containing at least one element selected from Ir, Pt, Au, Rh, Pd, Ag, Ni, and Cu, a fourth nonmagnetic layer containing at least one element selected from Ta, W, Nb, Mo, V, and Cr, and a fifth nonmagnetic layer containing at least one element of Si and Ge.

### CROSS-REFERENCE TO RELATED APPLICATION

This application is based upon and claims the benefit of priority from Japanese Patent Application No. 2024-159050, filed Sep. 13, 2024, the entire contents of which are incorporated herein by reference.

### FIELD

Embodiments described herein relate generally to a magnetic memory device.

### BACKGROUND

A magnetoresistive random access memory (MRAM) using a magnetoresistive effect element as a memory element is known.

### BRIEF DESCRIPTION OF THE DRAWINGS

FIG. 1 is a block diagram illustrating an example of an overall configuration of a magnetic memory device according to an embodiment.

FIG. 2 is a circuit diagram illustrating an example of a circuit configuration of a memory cell array included in the magnetic memory device according to the embodiment.

FIG. 3 is a perspective view illustrating an example of a structure of the memory cell array included in the magnetic memory device according to the embodiment.

FIG. 4 is a cross-sectional view illustrating an example of a cross-sectional configuration of a magnetoresistive effect element included in the magnetic memory device according to the embodiment.

FIG. 5 is a diagram illustrating an example of comparison of characteristics of the magnetoresistive effect element based on a difference in buffer layer.

FIG. 6 is a circuit diagram illustrating an example of the circuit configuration of the memory cell array included in the magnetic memory device according to a modification of the embodiment.

FIG. 7 is a cross-sectional view illustrating an example of a cross-sectional configuration of a memory cell included in the magnetic memory device according to the modification of the embodiment.

### DETAILED DESCRIPTION

In general, according to one embodiment, a magnetic memory device includes a magnetoresistive effect element. The magnetoresistive effect element includes a first ferromagnetic layer, a second ferromagnetic layer, a third ferromagnetic layer, a first nonmagnetic layer provided between the first ferromagnetic layer and the second ferromagnetic layer, a second nonmagnetic layer provided between the second ferromagnetic layer and the third ferromagnetic layer, a third nonmagnetic layer containing at least one element selected from iridium (Ir), platinum (Pt), gold (Au), rhodium (Rh), palladium (Pd), silver (Ag), nickel (Ni), and copper (Cu), a fourth nonmagnetic layer containing at least one element selected from tantalum (Ta), tungsten (W), niobium (Nb), molybdenum (Mo), vanadium (V), and chromium (Cr), and a fifth nonmagnetic layer containing at least one element of silicon (Si) and germanium (Ge). The second ferromagnetic layer is between the first ferromagnetic layer and the third ferromagnetic layer. The third ferromagnetic layer is between the second nonmagnetic layer and the third nonmagnetic layer. The fourth nonmagnetic layer is between the third nonmagnetic layer and the fifth nonmagnetic layer.

Hereinafter, an embodiment will be described with reference to the drawings. Note that, in the following description, components having the same function and configuration are denoted by the same reference numerals. In addition, in a case where a plurality of components having a common reference sign are distinguished, the common reference sign is added with a suffix to be distinguished. Note that, in a case where the components does not need to be particularly distinguished, only common reference signs are attached to the components, and no suffixes are attached thereto. Here, the suffix is not limited to a subscript or a superscript, and includes, for example, a lower case alphabet added to an end of the reference sign, an index meaning an array, and the like.

### 1. Embodiment

The magnetic memory device according to an embodiment will be described. The magnetic memory device according to the embodiment includes, for example, a perpendicular magnetization-type magnetic memory device using an element (hereinafter also referred to as an “MTJ element”) having a magnetoresistive effect by a magnetic tunnel junction (MTJ) as a resistance change element.

In the following description, a case where the MTJ element is applied as the resistance change element will be described. Further, for convenience of description, the resistance change element is referred to as a magnetoresistive effect element MTJ, and the embodiment will be described.

### 1.1 Overall Configuration of Magnetic Memory Device

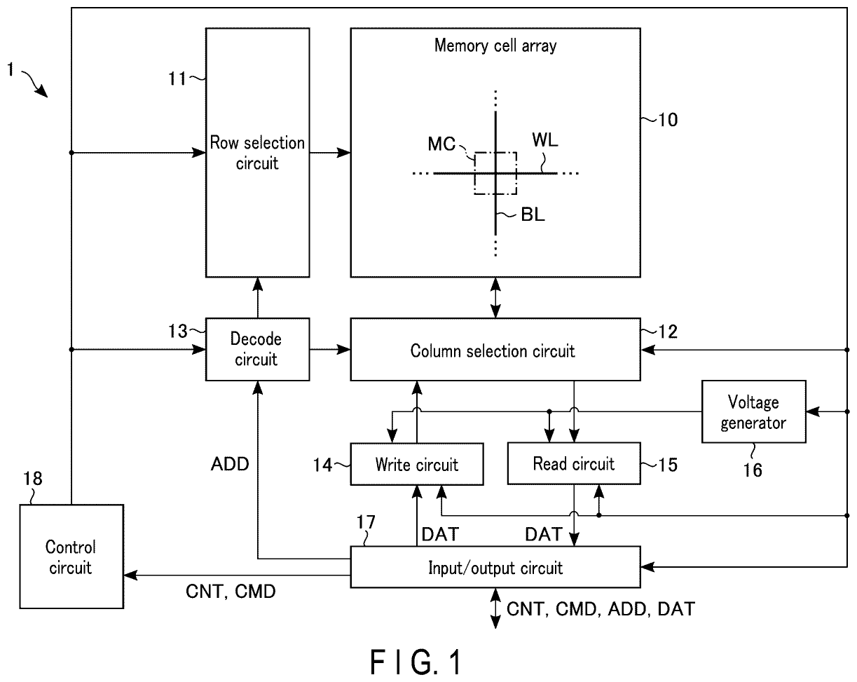

First, an example of an overall configuration of a magnetic memory device 1 will be described with reference to FIG. 1. FIG. 1 is a block diagram illustrating the example of the overall configuration of the magnetic memory device 1 according to the embodiment. Note that, in the example of FIG. 1, some connections between the components are indicated by arrow lines, but the connections between the components are not limited thereto.

As illustrated in FIG. 1, the magnetic memory device 1 includes a memory cell array 10, a row selection circuit 11, a column selection circuit 12, a decode circuit 13, a write circuit 14, a read circuit 15, a voltage generator 16, an input/output circuit 17, and a control circuit 18.

The memory cell array 10 includes a plurality of memory cells MC. Each memory cell MC is associated with a set of a row and a column. Specifically, the memory cells MC in the same row are coupled to the same word line WL, and the memory cells MC in the same column are coupled to the same bit line BL.

The row selection circuit 11 is a circuit that selects an interconnect (the word line WL) in a row direction. The row selection circuit 11 is coupled to the memory cell array 10 via the word line WL. The row selection circuit 11 is coupled to the decode circuit 13 and the control circuit 18. The row selection circuit 11 receives a decoded result of an address ADD (a row address) from the decode circuit 13. The row selection circuit 11 sets a corresponding word line WL to a selected state based on the decoded result of the address ADD.

The column selection circuit 12 is a circuit that selects an interconnect (the bit line BL) in a column direction. The column selection circuit 12 is coupled to the memory cell array 10 via the bit line BL. The column selection circuit 12 is coupled to the decode circuit 13, the write circuit 14, the read circuit 15, and the control circuit 18. The column selection circuit 12 receives a decoded result of an address ADD (a column address) from the decode circuit 13. The column selection circuit 12 sets a corresponding bit line BL to a selected state based on the decoded result of the address ADD.

The decode circuit 13 is a circuit that decodes the address ADD received from the input/output circuit 17. The decode circuit 13 is coupled to the row selection circuit 11, the column selection circuit 12, the input/output circuit 17, and the control circuit 18. The address ADD includes the column address and the row address. The decode circuit 13 transmits the decoded result of the address ADD to the row selection circuit 11 and the column selection circuit 12.

The write circuit 14 is a circuit that writes data DAT in the memory cell MC. The write circuit 14 is coupled to the column selection circuit 12, the voltage generator 16, the input/output circuit 17, and the control circuit 18. The write circuit 14 receives the data DAT from the input/output circuit 17. The write circuit 14 supplies a write current (voltage) based on the data DAT to the memory cell MC via the column selection circuit 12. The write circuit 14 includes, for example, a writing driver (not illustrated).

The read circuit 15 is a circuit that reads the data DAT from the memory cell MC. The read circuit 15 is coupled to the column selection circuit 12, the voltage generator 16, the input/output circuit 17, and the control circuit 18. The read circuit 15 reads the data DAT from the memory cell MC via the column selection circuit 12. The read circuit 15 transmits the read data DAT to the input/output circuit 17. The read circuit 15 includes, for example, a sense amplifier (not illustrated).

The voltage generator 16 is a circuit that generates voltages used for various operations in the magnetic memory device 1 by using a power supply voltage provided from an outside (not illustrated) of the magnetic memory device 1. The voltage generator 16 is coupled to the write circuit 14, the read circuit 15, and the control circuit 18. For example, the voltage generator 16 generates a voltage (current) used for a write operation and supplies the voltage to the write circuit 14. For example, the voltage generator 16 generates a voltage (current) used for a read operation and supplies the voltage to the read circuit 15.

The input/output circuit 17 is a circuit that inputs and outputs a control signal CNT, a command CMD, the address ADD, the data DAT, and the like to and from the outside of the magnetic memory device 1. The input/output circuit 17 is coupled to the decode circuit 13, the write circuit 14, the read circuit 15, and the control circuit 18. The input/output circuit 17 transmits the address ADD received from the outside of the magnetic memory device 1 to the decode circuit 13. The input/output circuit 17 transmits the command CMD and the control signal CNT received from the outside of the magnetic memory device 1 to the control circuit 18. The input/output circuit 17 transmits and receives various control signals CNT between the outside of the magnetic memory device 1 and the control circuit 18. The input/output circuit 17 transmits the data DAT received from the outside of the magnetic memory device 1 to the write circuit 14. The input/output circuit 17 transmits the data DAT received from the read circuit 15 to the outside of the magnetic memory device 1.

The control circuit 18 controls operations of the row selection circuit 11, the column selection circuit 12, the decode circuit 13, the write circuit 14, the read circuit 15, the voltage generator 16, and the input/output circuit 17 in the magnetic memory device 1 based on the control signal CNT and the command CMD. In addition, the control circuit 18 controls the write operation and the read operation.

### 1.2 Circuit Configuration of Memory Cell Array

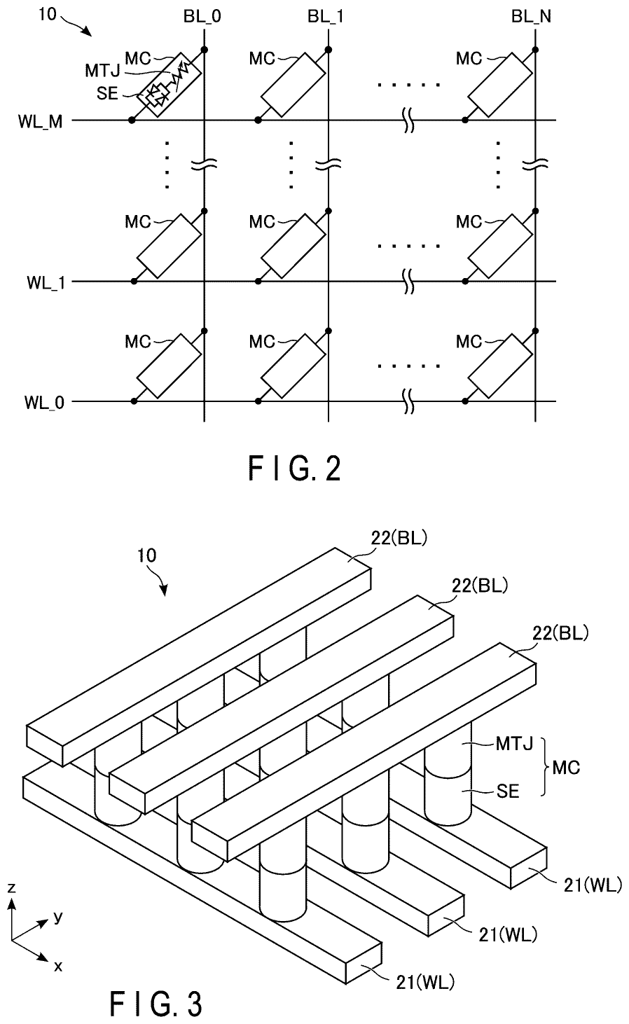

Next, an example of a circuit configuration of the memory cell array 10 will be described with reference to FIG. 2. FIG. 2 is a circuit diagram illustrating the example of the circuit configuration of the memory cell array 10 included in the magnetic memory device 1 according to the embodiment.

As illustrated in FIG. 2, M+1 word lines WL (WL_0, WL_1, . . . , and WL_M) and N+1 bit lines BL (BL_0, BL_1, . . . , and BL_N) are provided in the memory cell array 10. M and N are each a positive integer.

Each memory cell MC includes the magnetoresistive effect element MTJ and a switching element SE. The magnetoresistive effect element MTJ and the switching element SE are coupled in series between an associated bit line BL and word line WL. For example, one end of the magnetoresistive effect element MTJ is coupled to the bit line BL. The other end of the magnetoresistive effect element MTJ is coupled to one end of the switching element SE. The other end of the switching element SE is coupled to the word line WL. Note that, a coupling relationship between the magnetoresistive effect element MTJ and the switching element SE between the bit line BL and the word line WL may be reversed.

The magnetoresistive effect element MTJ corresponds to the MTJ element. The magnetoresistive effect element MTJ can store data in a nonvolatile manner based on a resistance value of the magnetoresistive effect element. For example, the memory cell MC including the magnetoresistive effect element MTJ in a high resistance state stores data “1”. The memory cell MC including the magnetoresistive effect element MTJ in a low resistance state stores data “0”. Data allocation associated with the resistance value of the magnetoresistive effect element MTJ may be another setting. The resistance state of the magnetoresistive effect element MTJ can change according to a current flowing through the magnetoresistive effect element MTJ.

The switching element SE functions as a switch that controls supply of the current to the magnetoresistive effect element MTJ during the write operation and the read operation to and from a corresponding magnetoresistive effect element MTJ. More specifically, for example, in a case where a voltage applied to the memory cell MC is less than a threshold voltage set in advance, the switching element SE in the memory cell MC cuts off the current as an insulator having a large resistance value (enters an OFF state). On the other hand, in a case where the voltage applied to the memory cell MC is equal to or higher than the threshold voltage, the switching element SE causes a current to flow as a conductor having a small resistance value (enters an ON state). That is, the switching element SE has a function of switching whether to flow or block the current according to magnitude of the voltage applied to the memory cell MC regardless of a direction of the flowing current.

The switching element SE may be, for example, a two-terminal switching element. In a case where a voltage applied between two terminals is less than the threshold voltage, the switching element SE is in a high resistance state in which almost no electricity flows or a non-conductive state. In a case where the voltage applied between two terminals is equal to or higher than the threshold voltage, the switching element SE is in a low resistance state, that is, an electrically conductive state. The switching element SE can have this function regardless of polarity of the voltage. Note that, as the switching element SE, another element such as a transistor may be used.

### 1.3 Structure of Memory Cell Array

Next, an example of a structure of the memory cell array will be described with reference to FIG. 3. FIG. 3 is a perspective view illustrating the example of the structure of the memory cell array 10 included in the magnetic memory device 1 according to the embodiment.

In the following description, an xyz orthogonal coordinate system is used. An X direction corresponds to an extending direction of the word line WL. A Y direction intersects the X direction and corresponds to an extending direction of the bit line BL. A Z direction intersects the X direction and the Y direction.

As illustrated in FIG. 3, the memory cell array 10 includes a plurality of interconnect layers 21 and a plurality of interconnect layers 22.

The interconnect layer 21 has a portion extending in the X direction. The interconnect layers 21 are provided side by side in the Y direction and are separated from each other. Each interconnect layer 21 functions as the word line WL.

The interconnect layer 22 has a portion extending in the Y direction. The interconnect layers 22 are provided above the interconnect layers 21 in the Z direction. The interconnect layers 22 are provided side by side in the X direction and are separated from each other. Each interconnect layer 22 functions as the bit line BL.

In top view from the Z direction, one memory cell MC is provided at each of portions where the interconnect layers 21 and the interconnect layers 22 intersect each other. In other words, each memory cell MC is provided in a columnar shape between an associated bit line BL and word line WL. In this example, the switching element SE is provided on the interconnect layer 21. The magnetoresistive effect element MTJ is provided on the switching element SE. The interconnect layer 22 is provided on the magnetoresistive effect element MTJ.

Although the magnetoresistive effect element MTJ is provided on the switching element SE in the example illustrated in FIG. 3, the switching element SE may be provided on the magnetoresistive effect element MTJ. In the example illustrated in FIG. 3, the bit line BL is provided above the word line WL, but the word line WL may be provided above the bit line BL. In addition, two or more memory cells MC may be stacked in the Z direction via the bit line BL or the word line WL.

### 1.4 Cross-Sectional Structure of Magnetoresistive Effect Element

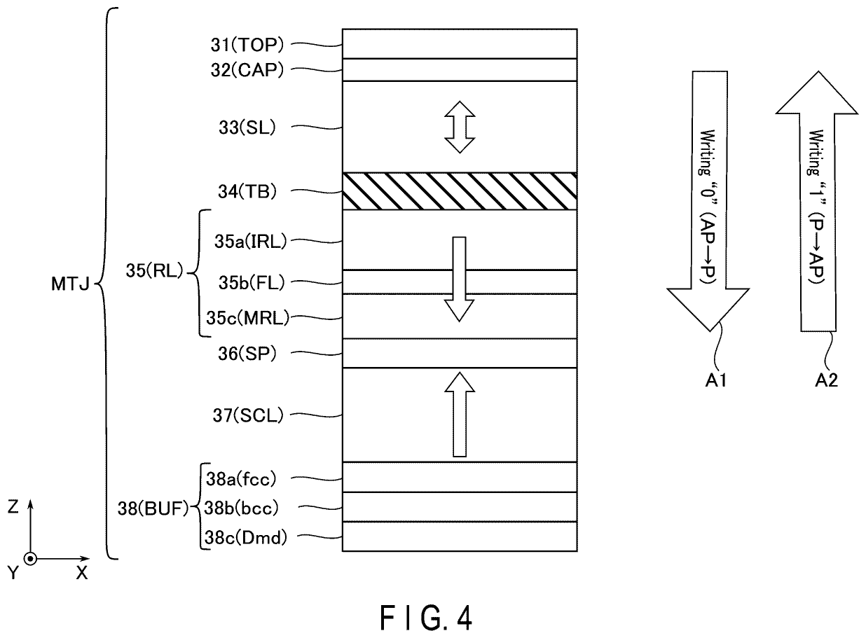

Next, an example of a cross-sectional structure of the magnetoresistive effect element MTJ will be described with reference to FIG. 4. FIG. 4 is a cross-sectional view illustrating an example of a cross-sectional configuration of the magnetoresistive effect element MTJ included in the magnetic memory device 1 according to the embodiment.

As illustrated in FIG. 4, the magnetoresistive effect element MTJ includes a nonmagnetic layer 31, a nonmagnetic layer 32, a ferromagnetic layer 33, a nonmagnetic layer 34, a stacked body (a stacked layer) 35, a nonmagnetic layer 36, a ferromagnetic layer 37, and a stacked body 38. Hereinafter, a stacked body (a stacked layer) 35 is called stacked body 35. The nonmagnetic layer 31 functions as, for example, a top layer TOP. The nonmagnetic layer 32 functions as, for example, a capping layer CAP. The ferromagnetic layer 33 functions as a storage layer SL. The nonmagnetic layer 34 functions as a tunnel barrier layer TB. The stacked body 35 functions as a reference layer RL. The nonmagnetic layer 36 functions as a spacer layer SP. The ferromagnetic layer 37 functions as a shift cancelling layer SCL. The stacked body 38 functions as a buffer layer BUF. Each of the storage layer SL, the reference layer RL, and the shift cancelling layer SCL can be regarded as a structure having ferromagnetism as a whole. The buffer layer BUF can be regarded as a structure having non-magnetism as a whole.

For example, the stacked body 38, the ferromagnetic layer 37, the nonmagnetic layer 36, the stacked body 35, the nonmagnetic layer 34, the ferromagnetic layer 33, the nonmagnetic layer 32, and the nonmagnetic layer 31 are stacked in this order from the word line WL side to the bit line BL side (in the Z direction). For example, a magnetization direction of a magnetic body constituting the magnetoresistive effect element MTJ is oriented in a direction perpendicular to each of film surfaces. Therefore, the magnetoresistive effect element MTJ functions as a perpendicular magnetization type MTJ element. Note that, the magnetoresistive effect element MTJ may include an additional layer (not illustrated) between the layers 31 to 38 described above.

The nonmagnetic layer 31 is a nonmagnetic conductor and has a function as a top electrode that improves electrical connectivity between an upper end of the magnetoresistive effect element MTJ and the bit line BL or the word line WL. The nonmagnetic layer 31 contains, for example, at least one element or compound selected from tungsten (W), tantalum (Ta), tantalum nitride (TaN), titanium (Ti), and titanium nitride (TiN).

The nonmagnetic layer 32 is a layer of a nonmagnetic material, and has a function of suppressing an increase in damping constant of the ferromagnetic layer 33 and reducing the write current. The nonmagnetic layer 32 contains, for example, magnesium oxide (MgO), aluminum oxide (AL₂O₃), or rare earth oxide. In addition, the nonmagnetic layer 32 may be a mixture of these oxides. That is, the nonmagnetic layer 32 is not limited to a binary compound including two kinds of elements, and can include a ternary compound including three kinds of elements, for example, magnesium aluminum oxide (MgAl₂O₄) or the like.

The ferromagnetic layer 33 has ferromagnetism and has an easy magnetization axis direction in a direction perpendicular to the film surface. The ferromagnetic layer 33 has a magnetization direction toward either the bit line BL side or the word line WL side in the Z direction. The ferromagnetic layer 33 contains iron (Fe) and can further contain at least one of cobalt (Co) and nickel (Ni). In addition, the ferromagnetic layer 33 can further contain boron (B). More specifically, for example, the ferromagnetic layer 33 contains iron cobalt boron (FeCoB) or iron boride (FeB), and can have a body-centered cubic (bcc) crystal structure.

The nonmagnetic layer 34 is a nonmagnetic insulator and contains, for example, magnesium oxide (MgO). The nonmagnetic layer 34 has a NaCl crystal structure in which the film surface is oriented in a (001) plane, and functions as a seed material to be a nucleus for growing a crystalline film from an interface with the ferromagnetic layer 33 in crystallization treatment of the ferromagnetic layer 33. The nonmagnetic layer 34 is provided between the ferromagnetic layer 33 and the stacked body 35, and forms a magnetic tunnel junction together with these two ferromagnetic layers.

The stacked body 35 can be regarded as one ferromagnetic layer as a whole, and has an easy magnetization axis direction in a direction perpendicular to the film surface. The stacked body 35 has a magnetization direction toward either the bit line BL side or the word line WL side in the Z direction. The magnetization direction of the stacked body 35 is fixed and is directed toward the ferromagnetic layer 37 in the example illustrated in FIG. 4. Note that, “the magnetization direction is fixed” means that the magnetization direction does not change by a current (spin torque) of a magnitude that can reverse the magnetization direction of the ferromagnetic layer 33.

More specifically, the stacked body 35 includes a ferromagnetic layer 35a, a nonmagnetic layer 35b, and a ferromagnetic layer 35c. The ferromagnetic layer 35a functions as an interface layer IL. The nonmagnetic layer 35b functions as a function layer FL. The ferromagnetic layer 35c functions as a main reference layer MRL 35c. For example, the ferromagnetic layer 35a, the nonmagnetic layer 35b, and the ferromagnetic layer 35c are stacked in this order between a lower surface of the nonmagnetic layer 34 and an upper surface of the nonmagnetic layer 36.

For example, an upper surface of the ferromagnetic layer 35a is in contact with the nonmagnetic layer 34. The ferromagnetic layer 35a is a ferromagnetic conductor, and may contain, for example, iron (Fe) and can further contain at least one of cobalt (Co) and nickel (Ni). In addition, the ferromagnetic layer 35a can further contain boron (B). More specifically, for example, the ferromagnetic layer 35a contains iron cobalt boron (FeCoB) or iron boride (FeB), and can have a body-centered cubic crystal structure.

The nonmagnetic layer 35b is provided between the ferromagnetic layer 35a and the ferromagnetic layer 35c. The nonmagnetic layer 35b is a nonmagnetic conductor and contains, for example, at least one metal selected from tantalum (Ta), hafnium (Hf), tungsten (W), zirconium (Zr), molybdenum (Mo), niobium (Nb), and titanium (Ti). The nonmagnetic layer 35b has a function of maintaining exchange coupling between the ferromagnetic layer 35a and the ferromagnetic layer 35c.

For example, a lower surface of the ferromagnetic layer 35c is in contact with the nonmagnetic layer 36. The ferromagnetic layer 35c can include, for example, at least one multilayer film selected from a multilayer film of cobalt (Co) and platinum (Pt) (Co/Pt multilayer film), a multilayer film of cobalt (Co) and nickel (Ni) (Co/Ni multilayer film), and a multilayer film of cobalt (Co) and palladium (Pd) (Co/Pd multilayer film). Note that, in the multilayer film constituting the ferromagnetic layer 35c, a layer in contact with the nonmagnetic layer 36 contains, for example, cobalt (Co).

The nonmagnetic layer 36 is a nonmagnetic conductor and contains, for example, at least one element selected from ruthenium (Ru), osmium (Os), rhodium (Rh), iridium (Ir), vanadium (V), and chromium (Cr).

The ferromagnetic layer 37 has an easy magnetization axis direction in a direction perpendicular to the film surface. The ferromagnetic layer 37 has a magnetization direction toward either the bit line BL side or the word line WL side in the Z direction. The magnetization direction of the ferromagnetic layer 37 is fixed similarly to the stacked body 35, and is directed toward the stacked body 35 in the example illustrated in FIG. 4. The ferromagnetic layer 37 functions as an anti-ferromagnetic coupling layer (AFL). The ferromagnetic layer 37 is a ferromagnetic conductor having a hexagonal close-packed (hcp) structure or face-centered cubic (fcc) crystal structure, and contains, for example, cobalt (Co). The ferromagnetic layer 37 can include at least one multilayer film selected from a multilayer film of cobalt (Co) and platinum (Pt) (Co/Pt multilayer film), a multilayer film of cobalt (Co) and nickel (Ni) (Co/Ni multilayer film), and a multilayer film of cobalt (Co) and palladium (Pd) (Co/Pd multilayer film).

The ferromagnetic layers 35c and 37 are antiferromagnetically coupled by the nonmagnetic layer 36. That is, the ferromagnetic layer 35c (more specifically, in the multilayer film constituting the ferromagnetic layer 35c, the layer in contact with the nonmagnetic layer 36) and the ferromagnetic layer 37 are coupled to have magnetization directions antiparallel to each other.

Therefore, in the example illustrated in FIG. 4, the magnetization directions of the ferromagnetic layers 35c and 37 face directions facing each other. Such a coupling structure of the ferromagnetic layer 35c, the nonmagnetic layer 36, and the ferromagnetic layer 37 is referred to as a synthetic anti-ferromagnetic (SAF) structure. The ferromagnetic layer 37 can offset an influence of a magnetic stray field of the stacked body 35 on the magnetization direction of the ferromagnetic layer 33.

Therefore, it is possible to suppress an occurrence of asymmetry in easiness of reversal of magnetization of the ferromagnetic layer 33 due to the magnetic stray field of the stacked body 35 or the like (that is, that the easiness of reversal in a case where the magnetization direction of the ferromagnetic layer 33 is reversed is different between a case where the magnetization direction is reversed from one direction to the other direction and a case where the magnetization direction is reversed in the opposite direction).

Note that, the ferromagnetic layer 37 can further contain at least one element of silicon (Si) and germanium (Ge). For example, iron (Fe) contained in the ferromagnetic layer 35a or the like has a property of easily diffusing into the SAF structure in a high-temperature environment such as an annealing treatment after film formation of each layer of the magnetoresistive effect element MTJ. For example, diffusion of iron (Fe) into the SAF structure weakens an anti-ferromagnetic coupling. On the other hand, silicon (Si) and germanium (Ge) have a property of suppressing diffusion of iron (Fe) into the SAF structure. That is, the ferromagnetic layer 37 contains silicon (Si) or germanium (Ge) and thus has a property of suppressing diffusion of iron (Fe) into the SAF structure. In the following description, an element that easily diffuses in the annealing treatment, such as iron (Fe), is also referred to as a “easily diffusing element”. In addition, an element having a function of suppressing diffusion of the easily diffusing element into another layer, such as silicon (Si) or germanium (Ge) described above, is also referred to as a “diffusion suppressing element”.

The stacked body 38 can be regarded as one nonmagnetic layer as a whole, and has a function as an electrode that improves electrical connectivity with the bit line BL or the word line WL. The stacked body 38 has a three-layer structure. The stacked body 38 includes nonmagnetic layers 38a, 38b, and 38c. The nonmagnetic layer 38a has a face-centered cubic crystal structure. The nonmagnetic layer 38b has a body-centered cubic crystal structure. The nonmagnetic layer 38c has a diamond structure. For example, the nonmagnetic layer 38a, the nonmagnetic layer 38b, and the nonmagnetic layer 38c are stacked in this order from a lower surface of the ferromagnetic layer 37 (shift cancelling layer SCL).

The nonmagnetic layer 38a is a nonmagnetic conductor having a face-centered cubic lattice, and contains, for example, at least one element selected from iridium (Ir), platinum (Pt), gold (Au), rhodium (Rh), palladium (Pd), silver (Ag), nickel (Ni), and copper (Cu). The nonmagnetic layer 38a is in contact with the ferromagnetic layer 37. The nonmagnetic layer 38a has a function of dividing a crystal structure of an upper layer (ferromagnetic layer 37) of the nonmagnetic layer 38a and a crystal structure of a lower layer (the nonmagnetic layer 38b).

The nonmagnetic layer 38b is a nonmagnetic conductor having a body-centered cubic lattice, and contains, for example, at least one element selected from tantalum (Ta), tungsten (W), niobium (Nb), molybdenum (Mo), vanadium (V), and chromium (Cr). The nonmagnetic layer 38b is in contact with a surface opposite to a surface of the nonmagnetic layer 38a in contact with the ferromagnetic layer 37. The nonmagnetic layer 38b has a function of dividing a crystal structure of an upper layer (nonmagnetic layer 38a) of the nonmagnetic layer 38b and a crystal structure of a lower layer (the nonmagnetic layer 38c).

The nonmagnetic layer 38c is a nonmagnetic conductor having a diamond lattice, and contains, for example, at least one element of silicon (Si) and germanium (Ge) that functions as the diffusion suppressing element. The nonmagnetic layer 38c is in contact with a surface opposite to a surface of the nonmagnetic layer 38b in contact with the nonmagnetic layer 38a. The nonmagnetic layer 38c functions as a supply source for supplying the diffusion suppressing element into the ferromagnetic layer 37 in a film formation stage (that is, a pre-stage of the annealing treatment). Thus, the stacked body 38 can allow the ferromagnetic layer 37 to exhibit a property of suppressing diffusion of iron (Fe) contained in the ferromagnetic layer 35a or the like into the SAF structure prior to the annealing treatment.

The above-described crystal structure can be confirmed by, for example, a transmission electron microscope (TEM) or the like. In addition, the above-described materials can be confirmed by electron energy loss spectroscopy (EELS), energy dispersive X-ray spectroscopy (EDX), or the like.

In the embodiment, a spin injection writing method is employed in which a write current is directly applied to the magnetoresistive effect element MTJ, a spin torque is injected into the storage layer SL and the reference layer RL by the write current, and the magnetization direction of the storage layer SL and the magnetization direction of the reference layer RL are controlled. The magnetoresistive effect element MTJ can take either the low resistance state or the high resistance state depending on whether a relative relationship between the magnetization directions of the storage layer SL and the reference layer RL is parallel or antiparallel.

In a case where a write current Ic0 of a certain magnitude is applied to the magnetoresistive effect element MTJ in a direction of an arrow A1 in FIG. 4, that is, in a direction from the storage layer SL toward the reference layer RL, the relative relationship between the magnetization directions of the storage layer SL and the reference layer RL is parallel. In the case of this parallel state, the resistance value of the magnetoresistive effect element MTJ is the lowest, and the magnetoresistive effect element MTJ is set to the low resistance state. This low resistance state is called a “parallel (P) state” and is defined as, for example, a state of data “0”.

In addition, in a case where a write current Ic1 larger than the write current Ic0 is applied to the magnetoresistive effect element MTJ in a direction of an arrow A2 in FIG. 4, that is, in a direction from the reference layer RL toward the storage layer SL (a direction opposite to the arrow A1), the relative relationship between the magnetization directions of the storage layer SL and the reference layer RL is antiparallel. In the case of this antiparallel state, the resistance value of the magnetoresistive effect element MTJ is the highest, and the magnetoresistive effect element MTJ is set to the high resistance state. This high resistance state is called an “anti-parallel (AP) state” and is defined as, for example, a state of data “1”.

Note that, in the following description, description will be made according to a data defining method described above, but a method of defining the data “1” and the data “0” is not limited to an example described above. For example, the P state may be defined as data “1”, and the AP state may be defined as data “0”.

### 1.5 Comparison of Characteristics of Magnetoresistive Effect Element Based on Difference in Buffer Layer

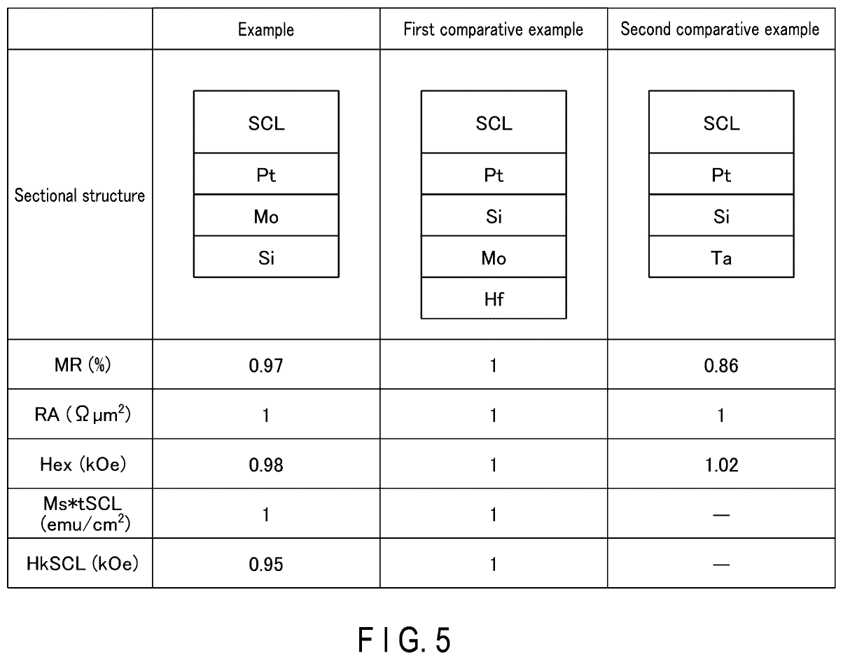

Next, comparison of characteristics of the magnetoresistive effect element MTJ based on a difference in the buffer layer BUF will be described with reference to FIG. 5. FIG. 5 is a diagram illustrating an example of comparison of characteristics of the magnetoresistive effect element MTJ based on the difference in the buffer layer BUF. FIG. 5 illustrates an example based on the present embodiment, a first comparative example, and a second comparative example. Characteristic values of each example illustrated in FIG. 5 indicate values normalized with the first comparative example being set as 1 (reference). In addition, a cross-sectional structure of each example is illustrated by extracting the shift cancelling layer SCL and the buffer layer BUF from the cross-sectional structure of the magnetoresistive effect element MTJ. Structures other than the buffer layer BUF are substantially the same in the example, the first comparative example, and the second comparative example.

As illustrated in FIG. 5, the buffer layer BUF of the example has a three-layer structure of silicon (Si), molybdenum (Mo), and platinum (Pt) from the lower layer. That is, the nonmagnetic layers 38a, 38b, and 38c are respectively platinum (Pt) having a face-centered cubic lattice, molybdenum (Mo) having a body-centered cubic lattice, and silicon (Si) having a diamond lattice. In contrast, the buffer layer BUF of the first comparative example has a four-layer structure of hafnium (Hf), molybdenum (Mo), silicon (Si), and platinum (Pt) from the lower layer. The buffer layer BUF of the second comparative example has a three-layer structure of tantalum (Ta), silicon (Si), and platinum (Pt) from the lower layer. In the example, platinum (Pt) having a face-centered cubic lattice and molybdenum (Mo) having a body-centered cubic lattice are provided between the shift cancelling layer SCL and Si. In contrast, in the first comparative example and the second comparative example, between the shift cancelling layers SCL and Si, platinum (Pt) having a face-centered cubic lattice is provided and a layer (for example, molybdenum (Mo)) having a body-centered cubic lattice is not provided.

First, comparing a magnetoresistance ratio MR, the magnetoresistance ratio MR of the example was 0.97 compared to the first comparative example, which was similar to that of the first comparative example. In contrast, the magnetoresistance ratio MR of the second comparative example was 0.86, which was lower than those of the example and the first comparative example.

Comparing a resistance area RA of the magnetoresistive element MTJ, area resistances RA of the example and the second comparative example were both 1, and the same results were obtained in the three examples regardless of the structure of the buffer layer BUF.

Comparing an index Hex corresponding to a magnitude of an external magnetic field necessary for reversing the magnetization direction of the reference layer RL, indexes Hex of the example and the second comparative example are respectively 0.98 and 1.02, and similar results were obtained in the three examples. For example, in order to obtain an ideal value as the index Hex, it is desirable that an amount of impurities (for example, iron (Fe)) that inhibit anti-ferromagnetic coupling in the SAF structure is small in the SAF structure. Similarly to the first comparative example and the second comparative example, the structure of the example can reduce an amount of easily diffusing elements such as iron (Fe) diffused into the SAF structure during the annealing treatment, and can suppress a decrease in the anti-ferromagnetic coupling.

Comparing saturation magnetization (Ms*tSCL) of the entire shift cancelling layer SCL, the value in the example was 1, and the same results were obtained in the example and the first comparative example regardless of the structure of the buffer layer BUF.

Comparing an anisotropic magnetic field (HkSCL) of the shift cancelling layer SCL, the value in the example was 0.95, and similar results were obtained in the example and the first comparative example regardless of the structure of the buffer layer BUF.

From the above results, comparing the example with the first comparative example, in the case of the buffer layer BUF having the three-layer structure shown in the example, similar result as the buffer layer BUF having the four-layer structure shown in the first comparative example can be obtained. That is, by providing platinum (Pt) having a face-centered cubic lattice and molybdenum (Mo) having a body-centered cubic lattice between the shift cancelling layer SCL and Si, similar results as the first comparative example is obtained. Therefore, with a configuration according to the present embodiment, the number of buffer layers BUF can be reduced from four layers to three layers. Therefore, manufacturing cost can be reduced. In addition, comparing the example with the second comparative example having a three-layer structure, by providing platinum (Pt) having a face-centered cubic lattice and molybdenum (Mo) having a body-centered cubic lattice between the shift cancelling layer SCL and Si, the magnetoresistance ratio MR is improved (a decrease in the magnetoresistance ratio MR is suppressed). By providing platinum (Pt) having a face-centered cubic lattice and molybdenum (Mo) having a body-centered cubic lattice between the shift cancelling layer SCL and Si having a diamond lattice, it is possible to suppress disturbance of the crystal structure of the shift cancelling layer SCL due to an influence of the crystal structure of the diamond lattice. That is, it is possible to suppress disturbance of an interface with the buffer layer BUF in the shift cancelling layer SCL. Therefore, deterioration of the magnetoresistance ratio MR can be suppressed.

### 1.6 Effects According to Present Embodiment

The magnetic memory device 1 of the present embodiment can suppress deterioration of performance of the magnetoresistive effect element MTJ. More specifically, in the configuration according to the embodiment, the buffer layer BUF can have a three-layer structure of the nonmagnetic layer 38a having a face-centered cubic lattice, the nonmagnetic layer 38b having a body-centered cubic lattice, and the nonmagnetic layer 38c having a diamond lattice from the shift cancelling layer SCL side. By providing the nonmagnetic layer 38a and the nonmagnetic layer 38b between the shift cancelling layer SCL and the nonmagnetic layer 38c, it is possible to suppress the disturbance of the crystal structure of the shift cancelling layer SCL. Therefore, the deterioration of the magnetoresistance ratio MR can be suppressed.

Furthermore, in the configuration according to the present embodiment, the nonmagnetic layer 38c contains at least one element of silicon (Si) and germanium (Ge). This makes it possible to reduce the amount of easily diffusing elements such as iron (Fe) diffused into the SAF structure during the annealing treatment, and to suppress the decrease in the anti-ferromagnetic coupling.

Furthermore, in the configuration according to the present embodiment, the buffer layer BUF can have a three-layer structure. This can reduce the manufacturing cost of the magnetoresistive effect element.

### 2. Modification

Note that, the present invention is not limited to the above-described embodiment, and various modifications can be applied.

For example, although a case where the two-terminal switching element is applied to the memory cell MC in the above-described embodiment as the switching element SE has been described, a metal oxide semiconductor (MOS) transistor may be applied as the switching element SE.

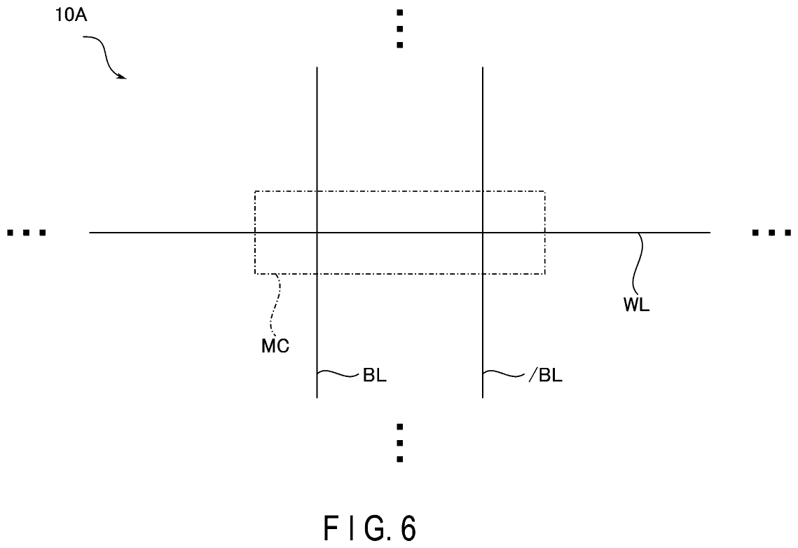

FIG. 6 is a circuit diagram illustrating an example of a circuit configuration of a memory cell array 10A of the magnetic memory device according to a modification of the embodiment. FIG. 6 corresponds to the memory cell array 10 in the magnetic memory device 1 described in FIG. 1 of the embodiment.

As illustrated in FIG. 6, the memory cell array 10A includes the memory cells MC each associated with a row and a column. Then, the memory cells MC in the same row are coupled to the same word line WL, and both ends of the memory cells MC in the same column are coupled to the same bit line BL and the same source line /BL.

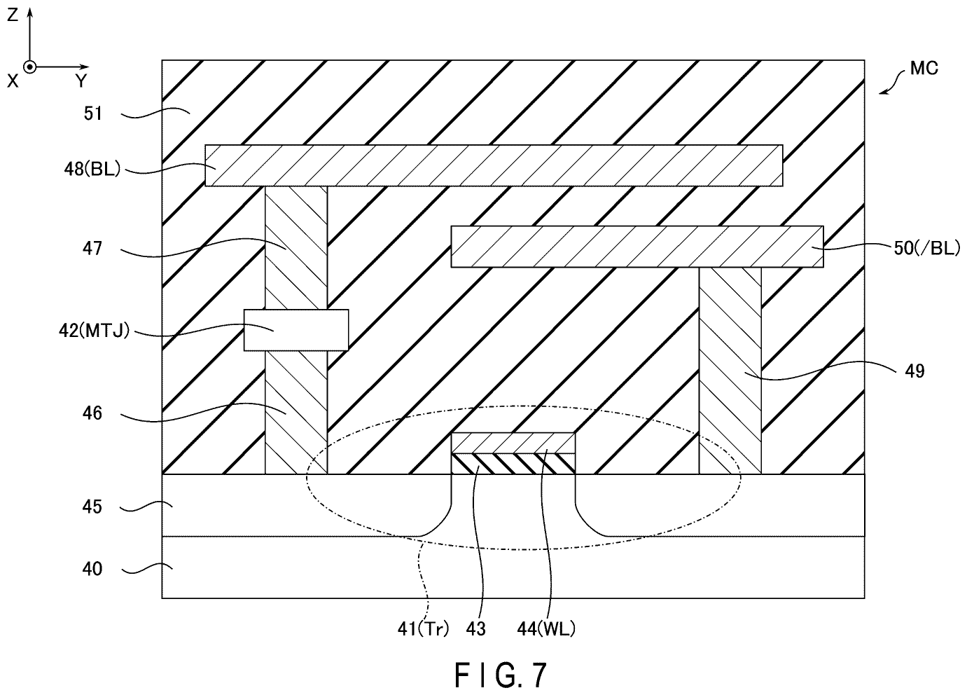

FIG. 7 is a cross-sectional view illustrating an example of a cross-sectional configuration of the memory cell MC of the magnetic memory device according to the modification of the embodiment. FIG. 7 corresponds to the memory cell MC described in FIG. 3 of the embodiment.

As illustrated in FIG. 7, the memory cell MC includes a selection transistor 41 (Tr) and a magnetoresistive effect element 42 (MTJ).

The selection transistor 41 is a MOS transistor. The selection transistor 41 is provided on a semiconductor substrate 40. The selection transistor 41 functions as the switching element SE. The selection transistor 41 includes a gate insulating film 43, a gate electrode 44, and two diffusion layer regions 45.

The gate insulating film 43 is provided on the semiconductor substrate 40. For example, the gate insulating film 43 contains silicon oxide (SiO).

The gate electrode 44 is provided on the gate insulating film 43. The gate electrode 44 functions as the word line WL. The gate electrode 44 extends, for example, in the X direction and is commonly coupled to a plurality of the selection transistors 41 arranged in the X direction.

The two diffusion layer regions 45 respectively function as a pair of source region and drain region. For example, the two diffusion layer regions 45 are provided in a region near an upper surface of the semiconductor substrate 40 at both ends of the gate electrode 44 in the Y direction.

A configuration of the magnetoresistive effect element 42 is similar to that of the magnetoresistive effect element MTJ illustrated in FIG. 4 of the embodiment.

A contact plug 46 is provided on a diffusion layer region 45 (one of the source region and the drain region) provided at a first end of the selection transistor 41. The contact plug 46 is coupled to a lower surface (a first end) of the magnetoresistive effect element 42. A contact plug 47 is provided on an upper surface (a second end) of the magnetoresistive effect element 42, and an upper surface of the contact plug 47 is coupled to an interconnect layer 48 functioning as the bit line BL. The interconnect layer 48 extends, for example, in the Y direction and is commonly coupled to second ends of a plurality of the magnetoresistive effect elements 42 (not illustrated) arranged in the Y direction.

A contact plug 49 is provided on a diffusion layer region 45 (the other of the source region and the drain region) provided at a second end of the selection transistor 41. The contact plug 49 is coupled to a lower surface of an interconnect layer 50 functioning as a bit line /BL. The interconnect layer 50 extends, for example, in the Y direction and is commonly coupled to second ends of the selection transistors 41 (not illustrated) arranged in the Y direction. The interconnect layers 48 and 50 are arranged, for example, in the Y direction. The interconnect layer 48 is located, for example, above the interconnect layer 50. Note that, the interconnect layers 48 and 50 are arranged avoiding physical and electrical interference with each other. The selection transistor 41, the magnetoresistive effect element 42, the gate insulating film 43, the gate electrode 44, the diffusion layer region 45, the contact plugs 46, 47, and 49, and the interconnect layers 48 and 50 are covered with an interlayer insulating film 51.

With the above configuration, even in a case where the MOS transistor that is a three-terminal switching element is applied to the switching element SE instead of the two-terminal switching element, the same effects as the embodiment can be obtained.

### 3. Others

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A magnetic memory device comprising a magnetoresistive effect element, wherein
the magnetoresistive effect element includes:
a first ferromagnetic layer;
a second ferromagnetic layer;
a third ferromagnetic layer;
a first nonmagnetic layer provided between the first ferromagnetic layer and the second ferromagnetic layer;
a second nonmagnetic layer provided between the second ferromagnetic layer and the third ferromagnetic layer;
a third nonmagnetic layer containing at least one element selected from iridium (Ir), platinum (Pt), gold (Au), rhodium (Rh), palladium (Pd), silver (Ag), nickel (Ni), and copper (Cu);
a fourth nonmagnetic layer containing at least one element selected from tantalum (Ta), tungsten (W), niobium (Nb), molybdenum (Mo), vanadium (V), and chromium (Cr); and
a fifth nonmagnetic layer containing at least one element of silicon (Si) and germanium (Ge),
the second ferromagnetic layer is between the first ferromagnetic layer and the third ferromagnetic layer,
the third ferromagnetic layer is between the second nonmagnetic layer and the third nonmagnetic layer, and
the fourth nonmagnetic layer is between the third nonmagnetic layer and the fifth nonmagnetic layer.

2. The magnetic memory device according to claim 1, wherein
the third nonmagnetic layer has a face-centered cubic lattice,
the fourth nonmagnetic layer has a body-centered cubic lattice, and
the fifth nonmagnetic layer has a diamond lattice.

3. The magnetic memory device according to claim 1, wherein
the third ferromagnetic layer contains cobalt (Co) and at least one of silicon (Si) and germanium (Ge).

4. The magnetic memory device according to claim 1, wherein
the first ferromagnetic layer contains iron (Fe).

5. The magnetic memory device according to claim 4, wherein
the first ferromagnetic layer further contains at least one of cobalt (Co) and nickel (Ni).

6. The magnetic memory device according to claim 4, wherein
the first ferromagnetic layer further contains boron (B).

7. The magnetic memory device according to claim 1, wherein
the second ferromagnetic layer contains iron (Fe).

8. The magnetic memory device according to claim 7, wherein
the second ferromagnetic layer further contains at least one of cobalt (Co) and nickel (Ni).

9. The magnetic memory device according to claim 7, wherein
the second ferromagnetic layer further contains boron (B).

10. The magnetic memory device according to claim 1, wherein
the first nonmagnetic layer contains an oxide containing magnesium (Mg).

11. The magnetic memory device according to claim 1, wherein
the second nonmagnetic layer contains at least one element selected from ruthenium (Ru), osmium (Os), rhodium (Rh), iridium (Ir), vanadium (V), and chromium (Cr).

12. The magnetic memory device according to claim 1, wherein
the second ferromagnetic layer and the third ferromagnetic layer have magnetization directions opposite to each other.

13. The magnetic memory device according to claim 1, wherein
the magnetoresistive effect element has:
a first resistance value in a case where a magnetization direction of the first ferromagnetic layer and a magnetization direction of the second ferromagnetic layer are in a parallel state; and
a second resistance value in a case where the magnetization direction of the first ferromagnetic layer and the magnetization direction of the second ferromagnetic layer are in an antiparallel state.

14. The magnetic memory device according to claim 13, wherein
the first resistance value is smaller than the second resistance value.

15. The magnetic memory device according to claim 1, further comprising a switching element coupled in series with the magnetoresistive effect element.

16. The magnetic memory device according to claim 15, wherein
the switching element is a two-terminal switching element.

17. The magnetic memory device according to claim 15, wherein
the switching element is a metal oxide semiconductor (MOS) transistor.
